(19) United States
(12) Patent Application Publication
(10) Pub. No.: US 2006/0126856 A1
(43) Pub. Date: Jun. 15, 2006

(54) Volume control method and audio device

(75) Inventors: Tsan-Nan Chien, Taipei City (TW); Tze-Liang Hsu, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Quanta Computer Inc.

(21) Appl. No.: 11/168,272

(22) Filed: Jun. 28, 2005

(30) Foreign Application Priority Data
Dec. 10, 2004 (TW) 93138346

(51) Int. Cl. H03G 3/20; H03G 3/00

(52) U.S. Cl. 381/57; 381/104; 381/107

(57) ABSTRACT

A volume control method. An audio device. A portable communication system. First, an audio signal is input. At least one environmental noise is detected. An output gain is then determined based on the environmental noise, and the audio signal is amplified based thereon. The environmental noise comprises noises from various directions and various positions, and the output gain is proportional to the amplitude of the environmental noise. A custom gain is further received, and a sound pressure level (SPL) of the environmental noise is calculated. Therefore the output gain can be determined by summing the sound pressure level and the custom gain.

### BACKGROUND

The invention relates to a volume control method, and in particular, to audio devices and portable communication systems capable of dynamically adjusting output volume according to environmental noise.

FIG. 1 shows a conventional audio device 100 comprising a volume controller 102, a memory device 104, a user interface 106, an audio generator 108 and a speaker 110. The speaker 110 is a part of a portable communication system, such as mobile phone. Electric signals are transformed to audio signals via the audio generator 108. The audio signals must be amplified to be audible sound waves, therefore through volume control in the volume controller 102, the audible sound waves are broadcast from the speaker 110 accordingly. The user interface 106 provides manual controllability, delivering a control signal CTRL# to the volume controller 102 to adjust an output gain controlling the loudness of the audible sound waves also refers to as “volume”. Conventional mobile phones generally comprise a memory device 104 for storage of custom values input from the user interface 106.

When in a quiet environment, the audible sound waves can be heard loud and clear without high output gain. Conversely, when in a noisy environment, higher output gain is required for audio recognition. Since the environment in which the portable communication system is used constantly changes, an auto-sensing and dynamic tuning mechanism is desirable.

### SUMMARY

An embodiment of the invention provides a volume control method comprising the following steps. First, an audio signal is input. At least one environmental noise is detected. An output gain is then determined based on the environmental noise, and the audio signal is amplified accordingly. The environmental noise comprises noises from various directions and various positions, and the output gain is proportional to the amplitude of the environmental noise. A custom gain is further received, and a sound pressure level (SPL) of the environmental noise is calculated. Thus the output gain can be determined by summing the sound pressure level and the custom gain.

Another embodiment provides an audio device, comprising an audio generator, a noise detector and a volume controller. The audio generator generates an audio signal, and the noise detector detects at least one environmental noise. The volume controller, coupled to the audio generator and the noise detector, determines an output gain based on the amplitude of the environment gain to amplify the audio signal, and outputs the audio signal. The volume controller comprises a processor and an amplifier. The processor calculates a sound pressure level (SPL) of the environmental noise, and generates a control signal. The amplifier receives the control signal to generate the output gain, such that the amplitude of the audio signal is amplified thereby. The audio device further comprises a user interface and a memory device. The user interface, coupled to the volume controller, receives a custom gain. The memory device, coupled to the volume controller, stores the custom gain. The amplifier generates the output gain by summing the sound pressure level and the custom gain. The audio device further comprises a speaker coupled to the volume controller, for broadcasting the audio signal.

Yet another embodiment of the invention provides a portable communication system comprising a communication module, an audio generator, a plurality of noise detectors, a volume controller and a memory device. The communication module receives at least one electromagnetic signal, and the audio generator coupled to the communication module, transforms the electromagnetic signal to an audio signal. The plurality of noise detectors detect at least one environmental noise. The volume controller coupled to the audio generator and the noise detectors, determines an output gain and amplifies the audio signal thereby. The user interface coupled to the volume controller, receives a custom gain, and the memory device coupled to the volume controller, stores the custom gain.

### DESCRIPTION OF THE DRAWINGS

The following detailed description, given by way of example and not intended to limit the invention solely to the embodiments described herein, will best be understood in conjunction with the accompanying drawings, in which:

FIG. 1 shows a conventional audio device 100;

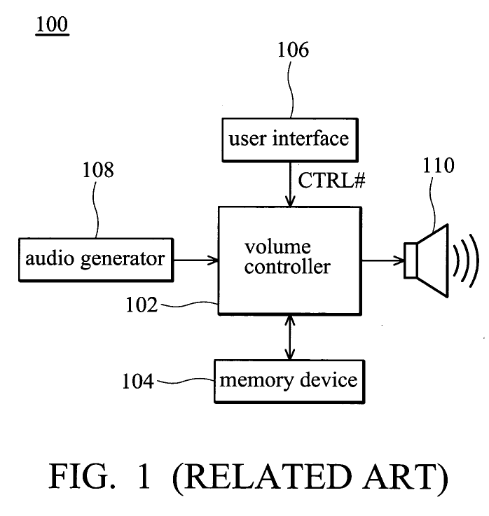

FIG. 2 shows an embodiment of an audio device 200;

FIG. 3 shows an embodiment of the portable communication system 300; and

FIG. 4 is a flowchart of an embodiment of the volume control method.

### DETAILED DESCRIPTION

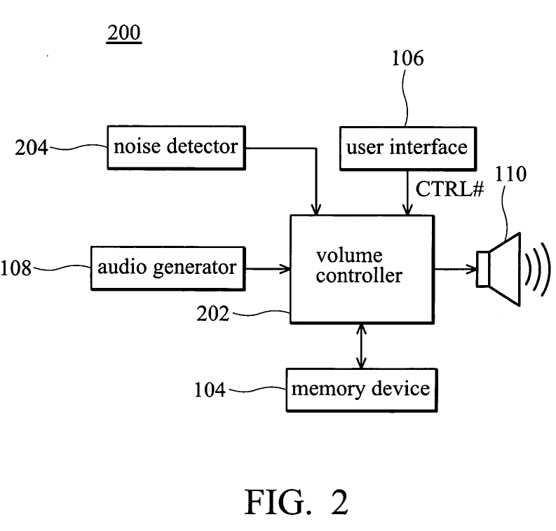

FIG. 2 shows an embodiment of an audio device 200 comprising a memory device 104, a user interface 106, an audio generator 108 and a speaker 110. Further, the audio device 200 comprises a volume controller 202 and a noise detector 204. The user interface 106 is coupled to the volume controller 202, for input of a custom gain. The memory device 104 is coupled to the volume controller 202, for storage of the custom gain. The speaker 110 is coupled to the volume controller 202 for sound wave broadcasting. The noise detector 204 comprising vibration films, coils, a Back-Electrets type board, a current amplifier and integrated circuits, is capable of detecting at least one environmental noise. The memory device 104 can be FLASH memory or DRAM. The volume controller 202 receives the detection results from the noise detector 204 and the audio signal from the audio generator 108, and determines an output gain based thereon. The audio signal is thus amplified by the output gain and broadcast through the speaker 110. The amplitude of audio signal is referred to as “Sound Pressure Level” (SPL), and the measurement unit is the Decibel (DB or DBA). The SPL formula is shown as:
SPL (DB)=20·log₁₀ (detected sound pressure/reference sound pressure), where

the reference sound pressure is 20·10⁻⁶ Pa,

the measurement unit of Pa is Newton/meter² (N/m²).

Since human ear sensitivity to high frequency and low frequency varies, the audio device 200 may further comprise an equalizer (now shown) for frequency balance. The output gain can be calculated as:
Gₒᵤₜ=Gₙₒᵢₛₑ

where

Gₒᵤₜ is the output gain, and

Gₙₒᵢₛₑ is the gain of the environmental noise.

Alternatively, the output gain can be as:
Gₒᵤₜ=Gₙₒᵢₛₑ·G_{custom}

where

Gₒᵤₜ is the output gain,

Gₙₒᵢₛₑ is the gain of the environmental noise, and

G_{custom} is the custom gain.

The calculation of the output gain is not limited thereto, however, any amplification based on environmental noise should be included in the scope of the invention.

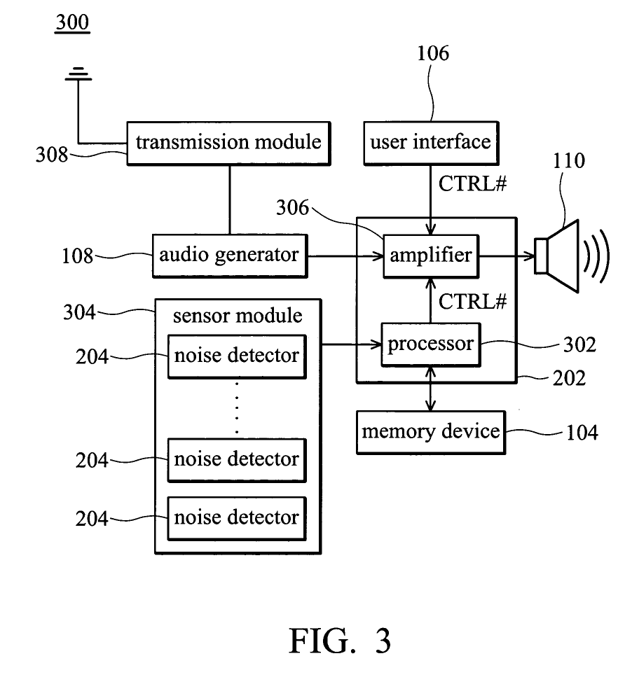

FIG. 3 shows an embodiment of the portable communication system 300 comprising the memory device 104, the user interface 106, the audio generator 108 and the speaker 110. Additionally, the portable communication system 300 comprises a sensor module 304 comprising a plurality of noise detectors 204, and a transmission module 308. The volume controller 202 comprises a processor 302 and an amplifier 306. The transmission module 308 receives and delivers electromagnetic signals to communicate wirelessly. The audio generator 108 is coupled to the transmission module 308 for transformation between the electromagnetic signals and the audio signals. The sensor module 304 comprises a plurality of noise detector 204 deposited at various positions for detection of a plurality of environmental noises from various directions. False detection may occur when a glitch is caused on a local noise detector 204 by user contact, or when part of the noise detector 204 fails to detect noise due to the cloth covering. Therefore the plurality of noise detectors 204 cooperate to distinguish from environmental noises and the false detections, increasing detection accuracy.

Thus, the detection result is delivered by the sensor module 304 to the processor 302 in the volume controller 202. A gain of the environmental noise is calculated by the volume controller 202, represented by the decibel (DB). Based on the gain of the environmental noise, the processor 302 generates a control signal CTRL# and the amplifier 306 amplifies the audio signal in response thereto. Further, a custom gain is read from the memory device 104 or received from the user interface 106, and added to the amplification of the audio signal, such that the broadcast sound wave can be heard loud and clear even in the presence of environmental noise. The portable communication device can be a mobile phone or a PDA. The control signal CTRL# is not limited and can be digital or analog.

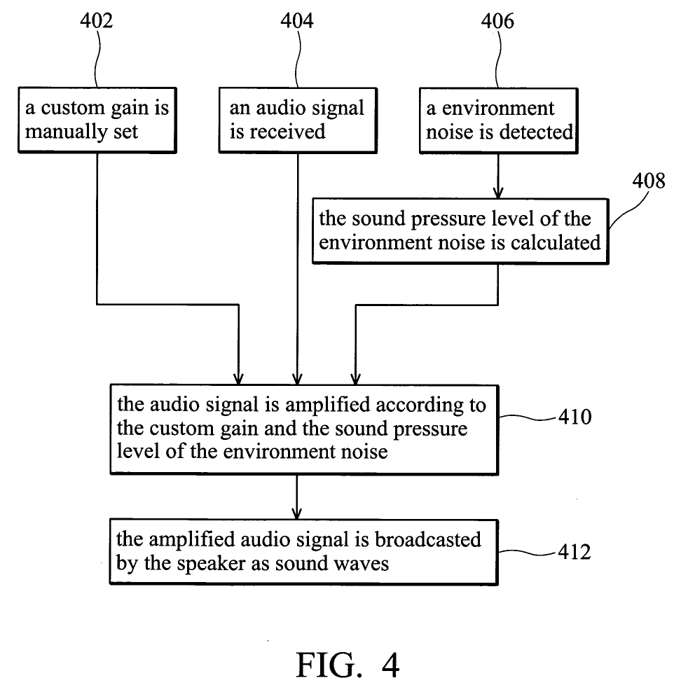

FIG. 4 is a flowchart of an embodiment of the volume control method. Three steps are simultaneously processed. First, in step 402, a custom gain is manually set. Second, in step 404, an audio signal is received. For example, in a mobile phone, the audio signal is obtained from transforming an electromagnetic signal. Third, in step 406, an environmental noise is detected. Thereafter in step 408, the sound pressure level of the environmental noise is calculated. In step 410, the audio signal is amplified according to the custom gain and the sound pressure level of the environmental noise. In step 412, the amplified audio signal is broadcast by the speaker as sound waves. The steps described proceed recursively as communication proceeds.

While the invention has been described by way of example and in terms of the preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A volume control method, comprising:
inputting an audio signal;
detecting at least one environmental noise;
determining an output gain based on the environmental noise; and
amplifying the audio signal by the output gain.

2. The volume control method as claimed in claim 1, wherein:
the environmental noise comprises sounds from various directions and various positions; and
the output gain is proportional to the amplitude of the environmental noise.

3. The volume control method as claimed in claim 1, further comprising receiving a custom gain, wherein:
the step of determining the output gain comprises:
calculating a sound pressure level (SPL) of the environmental noise; and
the output gain is determined by summing the sound pressure level and the custom gain.

4. An audio device, comprising:
an audio generator, for generating an audio signal;
a noise detector, for detecting at least one environmental noise; and
a volume controller, coupled to the audio generator and the noise detector, determining an output gain based on the amplitude of the environment gain to amplify the audio signal, and outputting the audio signal.

5. The audio device as claimed in claim 4, wherein the volume controller comprises:
a processor, for calculating a sound pressure level (SPL) of the environmental noise, and generating a control signal; and
an amplifier, for receiving the control signal to generate the output gain, such that the amplitude of the audio signal is amplified thereby.

6. The audio device as claimed in claim 5, further comprising:
a user interface, coupled to the volume controller, for receiving a custom gain; and
a memory device, coupled to the volume controller, for storage of the custom gain; wherein:
the amplifier generates the output gain by summing the sound pressure level and the custom gain.

7. The audio device as claimed in claim 4, further comprising:
a speaker, coupled to the volume controller, for broadcasting the audio signal.

8. A portable communication system, comprising:
a communication module, receiving at least one electromagnetic signal;
an audio generator, coupled to the communication module, transforming the electromagnetic signal to an audio signal;
a plurality of noise detectors, detecting at least one environmental noise;
a volume controller, coupled to the audio generator and the noise detectors, determining an output gain and amplifying the audio signal thereby;
a user interface, coupled to the volume controller, for receiving a custom gain; and
a memory device, coupled to the volume controller, for storage of the custom gain.

9. The portable communication system as claimed in claim 8, wherein:
the environmental noise comprises noises from various directions and various positions; and
the output gain is determined based on the amplitude of the environmental noise.

10. The portable communication system as claimed in claim 9, wherein the volume controller comprises:
a processor, for calculating a sound pressure level (SPL) of the environmental noise, and generating a control signal; and
an amplifier, for receiving the control signal to generate the output gain, such that the amplitude of the audio signal is amplified thereby.

11. The portable communication system as claimed in claim 10, wherein the output gain is determined by summing the sound pressure level and the custom gain.

12. The portable communication system as claimed in claim 8, further comprising:
a speaker, coupled to the volume controller, for broadcasting the audio signal.
